(19) United States
(12) Patent Application Publication
(10) Pub. No.: US 2008/0106999 A1
(43) Pub. Date: May 8, 2008

(54) Semiconductor Laser Apparatus, Method for Manufacturing the Same, and Optical Pickup Apparatus Using the Same

(75) Inventors: Satoru FUKUMOTO, Higashihiroshima-shi (JP); Nobumasa Kaneko, Higashihiroshima-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/861,015

(22) Filed: Sep. 25, 2007

(30) Foreign Application Priority Data
Sep. 26, 2006 (JP) 2006-261534

(51) Int. Cl. G11B 7/00; H05K 7/20

(52) U.S. Cl. 369/121; 361/711

(57) ABSTRACT

There is provided a semiconductor laser apparatus capable of sufficiently discharging heat generated at a semiconductor laser element, having a simple manufacturing step, and capable of adjusting an optical path length, as well as a method for manufacturing the same. A laser chip is connected through a block and a plate to a housing. Further, the plate is partially exposed from a connecting surface between the block and the plate, and when disposed in the housing, the semiconductor chip and the block are inserted from an outside of the housing to an inside thereof, and the plate is exposed outwardly from the housing. An optical axis of an output light beam from the laser chip is in parallel to a ground plane of the housing.

### CROSS-REFERENCE TO RELATED APPLICATION

This application claims priority to Japanese Patent Application No. 2006-261534, which was filed on Sep. 26, 2006, the contents of which are incorporated herein by reference in its entirety.

### BACKGROUND OF THE INVENTION

1. Field of the Invention

The present invention relates to a semiconductor laser apparatus which is preferably mounted on an optical disk recording/reproducing apparatus, a method for manufacturing the same, and an optical pickup apparatus using the same.

2. Description of the Related Art

The optical pickup apparatus for recording and reproducing data in an optical drive such as a compact disk (CD) drive, or a digital versatile disk (DVD) drive includes a semiconductor laser element as a light source, and a light-receiving element for receiving a reflected light beam from a disk. A laser beam emitted from the light source is adjusted so that a size of its light spot becomes smallest on a recording surface of a CD or a DVD. The laser beam reflected on the recording surface is received on a photodetector in the optical pickup apparatus, and is then converted to data.

Laser beams having wavelengths of 790 nm, 650 nm, and 405 nm are used for CDs, DVDs, and next-generation DVDs such as a blue-ray disk or a high definition digital versatile disk (HD DVD), respectively. The optical pickup drive corresponding to a plurality of standards mounts the plurality of optical pickup apparatuses, or the optical pickup apparatus which incorporates a plurality of laser light sources. Further, there is proposed a special recording medium called a digital versatile disk-random access memory (DVD-RAM), which is capable of recording on lands and grooves thereof.

In a semiconductor laser apparatus according to the related art, an optical element sub-carrier on which a light-emitting element is mounted is surrounded by a frame, and a lower-end face side of a base-lead including a mounted portion of the light-emitting element is in contact with a bottom portion of the frame (refer to Japanese Unexamined Patent Publication JP-A 9-21723 (1997)). FIG. 8 is a perspective view illustrating a semiconductor laser apparatus 20 according to the related art. The semiconductor laser apparatus 20 is inserted into a through-hole which is provided on a surface of a housing perpendicular to an optical axis of an output light beam emitted from the semiconductor laser apparatus 20, and fixed to the housing. When a light beam is emitted by the semiconductor laser apparatus 20, it is possible to change a position of the semiconductor laser apparatus 20 on the housing surface perpendicular to an optical axis in a light emitting direction by changing a position of the through-hole. Accordingly, an irradiated position of the laser beam can be adjusted. In addition, by means of a production system of the semiconductor laser apparatus according to the related art, a base holder on which a base is mounted can be linearly moved along a linear rail, and then a movement of the base from the base holder having a ladder shape to a production processing apparatus, and a movement of the base from the production processing apparatus to the base holder having a ladder shape can be carried out by using an arm. Therefore, this production system has a simple structure, sure operation, and a high production efficiency (refer to JP-A 2003-86480).

When the semiconductor laser apparatus disclosed in JP-A 9-21728 (1997) operates, the light-emitting element produces heat upon emitting a laser beam. The lower-end face side of the base-lead including the mounted portion of the light-emitting element is in contact with the bottom portion of the frame, and additionally the frame is mounted on the housing. Therefore, the heat generated from the light-emitting element is conducted through the mounted portion of the light-emitting element, the base-lead, and the frame to a main body of the housing, and is discharged from the main body of the housing. However, it is difficult to sufficiently discharge the heat generated from the light-emitting element, only by discharging the heat from the main body of the housing. Therefore, when the semiconductor laser apparatus is used over a long time period, the light-emitting element may possibly be gradually deteriorated, resulting in a reduction of its reliability and its lifetime. In addition, the optical axis of the output light beam emitted from the light-emitting element is deviated under an influence of distortion of the housing through the base-lead and the frame. Therefore, reliability of the semiconductor laser apparatus is reduced.

Further, the semiconductor laser apparatus 20 shown in FIG. 8 is fixed to a surface perpendicular to the optical axis of the output light beam emitted from the semiconductor laser apparatus 20. Therefore, it is possible to adjust a position on the surface perpendicular to the optical axis of the output light beam by adjusting a position of the through-hole which is provided on the housing, but it is not possible to adjust a position in a light-emitting direction, that is, an optical path length from a light-emitting position of a laser beam to a light-irradiated position thereof.

### SUMMARY OF THE INVENTION

An object of the invention is to provide a semiconductor laser apparatus capable of sufficiently discharging heat generated at a semiconductor laser element, of being manufactured in a simple manufacturing step, and of adjusting an optical path length, as well as a method for manufacturing the same.

The invention provides a semiconductor laser apparatus comprising:

a plate for connecting with a housing;

a block connected to one surface of the plate which is perpendicular to a thickness direction thereof; and

a laser chip which is connected to a surface opposite to a surface of the block to which the plate is connected,

wherein the plate is provided with an exposed portion which is partially exposed in the surface of the plate to which the block is connected, and an optical axis of an output light beam of the laser chip is perpendicular to the thickness direction of the plate.

According to the invention, the laser chip is connected to the block, and the block is connected to the plate for connecting with the housing. Therefore, the laser ship is less affected by mechanical distortion of the housing than it is directly connected to the housing. Further, the plate is partially exposed from a connecting surface between the block and the plate, and thereby the semiconductor chip, a circuit board, and the block are inserted from an outside of the housing, and the exposed portion of the plate is connected to an outside surface of the housing. The plate is exposed outwardly from the housing, and thereby heat generated from the semiconductor laser chip in the housing is efficiently discharged through the block to the plate, and to an outside of the housing. Accordingly, deterioration of the semiconductor laser apparatus is prevented, and thereby its reliability is improved, and its lifetime is increased. Further, the laser chip is fixed to a surface parallel to the optical axis of the output light beam, and thereby it is possible to adjust a position on the surface parallel to the optical axis of the output light beam by adjusting a position of the through-hole which is provided in the housing. By adjusting a position as described above, it is possible to adjust an optical path length from a light-emitting position of a laser beam to a light-irradiated position thereof, without changing a size of the housing.

Further, in the invention, it is preferable that the semiconductor laser apparatus further comprises a circuit board which is connected to a surface of the block which surface is opposite to the surface of the block to which the plate is connected, and the laser chip and the circuit board are electrically connected to each other.

According to the invention, the circuit board is further connected to the block, and is electrically connected to the laser chip. By mounting the circuit board on the block, a small-footprint is achieved.

Further, in the invention, it is preferable that the circuit board is a flexible board.

According to the invention, the circuit board is a flexible printed circuit board (abbreviated as a FPC), and the FPC is a flexible board which has a structure that a circuit formed by precisely etching a copper foil is coated with a polyimide film excellent in an insulating property and a heat-resisting property. The FPC is easily machined, and incorporates an electronic circuit in a narrow space. Therefore, electronic apparatuses are downsized, and a degree of freedom with respect to a board shape is improved.

Further, in the invention, it is preferable that the exposed portion is symmetric with respect to a center point of the surface of the block to which the plate is connected.

According to the invention, the exposed portion is symmetric with respect to a center point of the surface of the block to which the plate is connected. Therefore, when the semiconductor laser apparatus is inserted from an outside of the housing and fixed to the housing, the connecting portion with the outside surface of the housing becomes symmetric, thereby further improving stability of the connection.

Further, in the invention, it is preferable that the exposed portion is symmetric with respect to a straight line passing though a center point of the surface of the block to which the plate is connected, and perpendicular to a thickness direction of the plate.

According to the invention, the exposed portion is symmetric with respect to a straight line passing though a center point of the surface of the block to which the plate is connected, and perpendicular to a thickness direction of the plate. Therefore, when the semiconductor laser apparatus is inserted from an outside of the housing and fixed to the housing, the connecting portion with the outside surface of the housing becomes symmetric, thereby further improving stability of the connection.

Further, in the invention, it is preferable that the surface of the block to which the plate is connected is entirely connected to the plate, and an area of the surface of the plate to which the block is connected is larger than that of the surface of the block to which the plate is connected.

According to the invention, the surface of the block to which the plate is connected is entirely connected to the plate, and the area of the surface of the plate to which the block is connected is larger than that of the surface of the block to which the plate is connected. One surface of the block is entirely connected to the plate, and the plate has a wide area, and thereby an efficiency of heat discharge is improved. Moreover, stability of the connection with the housing is improved.

Further, in the invention, it is preferable that the laser chip is connected through a sub-mount member to the block, and the sub-mount has good heat conductivity, good heat discharge capability, and a buffering function.

According to the invention, the laser chip is connected through the sub-mount member to the block, and the sub-mount has significantly high heat conductivity, is excellent in heat discharge capability, and has a buffering function for reducing a breakdown caused by stress produced by a difference in a heat expansion coefficient between the block and the semiconductor laser chip. Therefore, deterioration of the semiconductor laser apparatus is prevented, and thereby its reliability is improved and its lifetime is increased.

Further, The invention provides a group of the semiconductor laser apparatuses comprising:

an elongated plate;

a plurality of blocks which are connected to one surface of the elongated plate which is perpendicular to a thickness direction of the elongated plate in a line at certain intervals in a longitudinal direction of the elongated plate; and

a laser chip which is connected to a surface opposite to a surface of the block to which the elongated plate is connected,

wherein an optical axis of an output light beam of the laser chip is perpendicular to the thickness direction of the elongated plate.

According to the invention, the plurality of blocks which are connected to the surface perpendicular to the thickness direction of the elongated plate of the group of the semiconductor laser apparatuses in a line at certain intervals in the longitudinal direction of the elongated plate, and the laser chip is mounted on each block. By making production and inspection regarding the block connected to the plate as a unit, simplification of production steps can be realized.

Further, the invention provides a method for manufacturing the semiconductor laser apparatus comprising the steps of:

providing the group of the semiconductor laser apparatuses mentioned above; and

dividing the elongated plate of the group of the semiconductor laser apparatuses between the adjacent blocks.

Further, according to the invention, the elongated plate of the group of the semiconductor laser apparatuses to which the plurality of blocks are connected is divided between the adjacent blocks with respect to each block, as individual semiconductor laser apparatuses. The elongated plate is divided after all components necessary for the semiconductor laser apparatus are mounted thereon, thus enabling simplification of production steps and improvement of transporting efficiency.

Further, the invention provides an optical pickup apparatus comprising:

the semiconductor laser apparatus mentioned above; and

a housing having a through-hole,

wherein an area of opening of the through-hole is larger than that of a surface perpendicular to a thickness direction of the block, and at least the laser chip of the semiconductor laser apparatus is inserted into the through-hole so as to be positioned in the housing, and the exposed portion is fixed to an outside surface of the housing so as to partially overlap with each other.

Further, according to the invention, at least the laser chip of the semiconductor laser apparatus is inserted into the through-hole so as to be positioned in the housing, and the exposed portion is fixed to the outside surface of the housing so as to partially overlap with each other. By exposing the plate of the semiconductor laser apparatus outwardly from the housing, heat generated from the semiconductor laser chip is discharged from the plate, and thereby an efficiency of heat discharge is improved compared with heat discharge from a main body of the housing in a conventional manner. Therefore, the heat generated from the semiconductor laser apparatus is sufficiently discharged, and thus deterioration of the semiconductor laser apparatus is prevented, and thereby its reliability is improved and its lifetime is increased.

Further, the laser chip is fixed to a surface parallel to the optical axis of the output light beam, and thereby it is possible to adjust a position on the surface parallel to the optical axis of the output light beam by adjusting a position of the through-hole which is provided in the housing. By adjusting the position as described above, an optical path length from a light-emitting position of a laser beam to a light-irradiated position thereof is adjusted, without changing a size of the housing. Therefore, there is provided the optical pickup apparatus corresponding to various wavelengths.

### BRIEF DESCRIPTION OF THE DRAWINGS

Other and further objects, features, and advantages of the invention will be more explicit from the following detailed description taken with reference to the drawings wherein:

FIGS. 1A to 1C are views illustrating a semiconductor laser apparatus according to a first embodiment of the invention;

FIGS. 2A to 2C are views illustrating a semiconductor laser apparatus according to a second embodiment of the invention;

FIGS. 3A to 3C are views illustrating a semiconductor laser apparatus according to a third embodiment of the invention;

FIG. 4 is a perspective view illustrating a method for setting the semiconductor laser apparatus;

FIG. 5 is a view illustrating a method for setting the semiconductor laser apparatus;

FIGS. 6A to 6D are bottom views illustrating the semiconductor laser apparatus of the invention;

FIGS. 7A and 7B are views illustrating a group of the semiconductor laser apparatuses of the invention; and

FIG. 8 is a semiconductor laser apparatus according to the related art.

### DETAILED DESCRIPTION

Hereinafter, referring to the drawings, preferred embodiments of the invention will be described in detail.

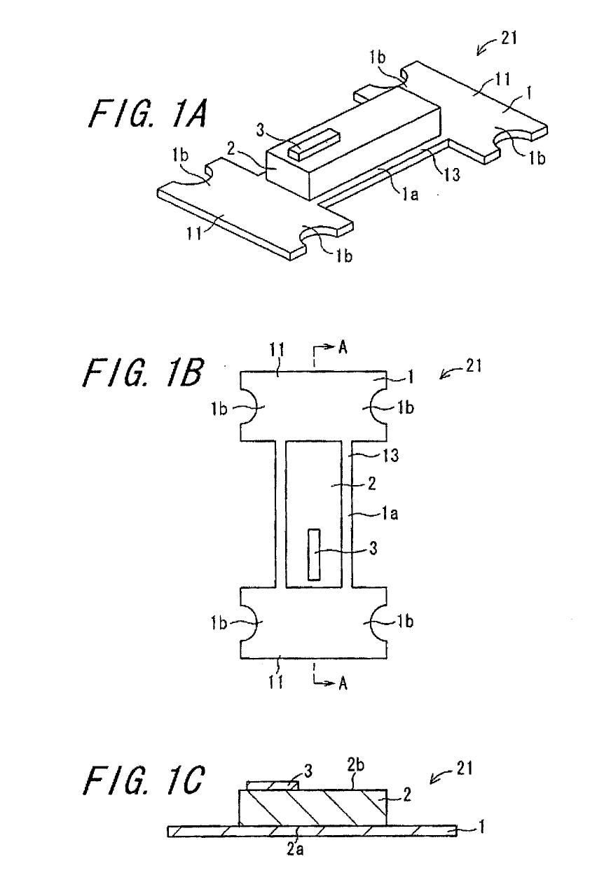

FIG. 1A is a perspective view illustrating a semiconductor laser apparatus 21 according to a first embodiment of the invention, FIG. 1B is a plan view thereof, and FIG. 1C is a cross-section view taken on cross-sectional line A-A in FIG. 1B. The semiconductor laser apparatus 21 includes a plate 1, a block 2, and a laser chip 3. The plate 1 is a member for connecting with a housing, and includes a rectangular connection portion 1a to which a block 2 is connected, and an exposing portion 11 which is provided on both sides of a longitudinal direction of the connection portion 1a and has a larger width than that of the connection portion 1a. That is, the plate 1 is provided with an exposed portion 11 which is partially exposed in a surface of the plate 1 connected to the block 2. The block 2 is formed in a form of a rectangular parallelepiped, and is connected to one surface of the plate 1 which is perpendicular to a thickness direction of the connection portion 1a of the plate 1. The laser chip 3 is connected to a surface 2b opposite to a surface 2a of the block 2 to which the connection portion 1a of the plate 1 is connected. An optical axis of an output light beam of the laser chip 3 is perpendicular to a thickness direction of the plate 1.

That is, the plate 1 has a shape which has convex portions 1b projecting in a width direction at four corners of a base body 13 having a rectangular shape, and the block 2 having a rectangular parallelepiped shape is connected to a center portion of the base body 13. That is, the center portion of the base body 13 corresponds to the connection portion 1a. In addition, the laser chip 3 is connected to the block 2 so that an elongated direction of the block 2 is in parallel to the optical axis of the output light beam.

The semiconductor laser apparatus 21 is manufactured by individually dividing the one in which the semiconductor laser apparatuses have been connected to each other in a form of a ladder. Before dividing it, the convex portions 1b of the plate 1 are connected to convex portions 1b of the plate of the adjacent semiconductor laser apparatus. The plate 1 and the block 2 contain, for example, a metal material in order to ensure a discharge capability for heat generated from the laser chip 3.

A laser chip 3 is connected to a block 2, and the block 2 is connected to a plate 1 for connecting with a housing of an optical pickup apparatus. Accordingly, the laser ship 1 is less affected by mechanical distortion of the housing than it is directly connected to the housing. Further, the plate 1 is partially exposed from a connecting surface between the block 2 and the plate 1, and thereby when disposed in the housing, the semiconductor chip 3 and the block 2 are inserted from an outside of the housing, and the exposed portion 11 of the plate 1 is connected to an outside surface of the housing. The plate 1 is exposed outwardly from the housing, and thereby the heat generated from the laser chip 3 in the housing is efficiently discharged trough the block 2 to the plate 1, and to an outside of the housing. Accordingly, deterioration of the semiconductor laser apparatus can be prevented, and thereby its reliability can be improved, and its lifetime can be increased. Further, an optical axis of an output light beam of the laser chip 3 is perpendicular to a thickness direction of the plate 1, that is, in parallel to a ground plane of the housing, and thereby it becomes possible to adjust a position on the surface parallel to the optical axis of the output light beam by adjusting a position of the through-hole which is provided in the housing. By adjusting a position as described above, it becomes possible to adjust an optical path length from a light-emitting position of a laser beam to a light-irradiated position thereof, without changing a size of the housing.

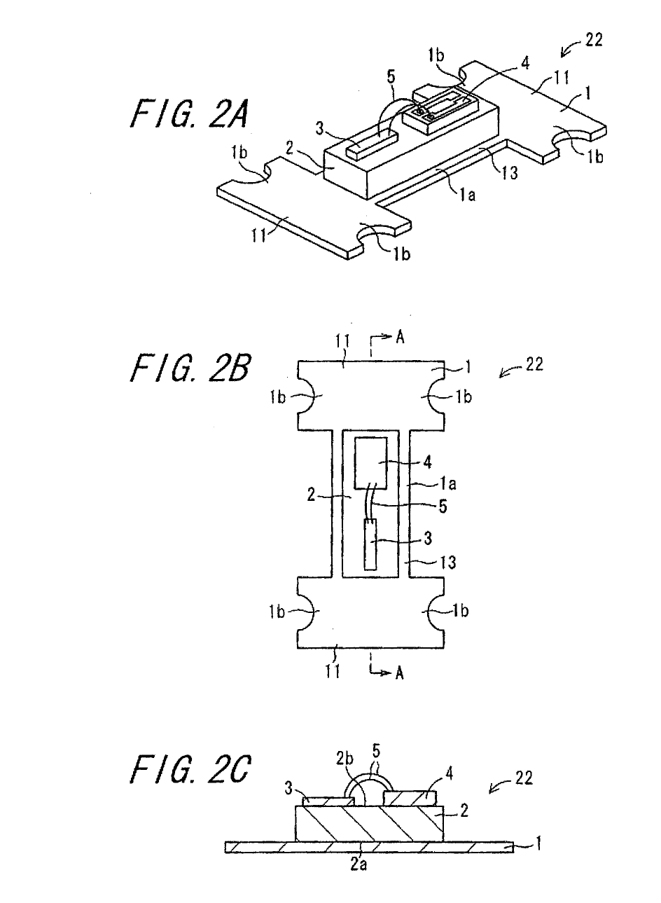

FIG. 2A is a perspective view illustrating a semiconductor laser apparatus 22 according to a second embodiment of the invention, FIG. 2B is a plan view thereof, and FIG. 2C is a cross-section view taken on cross-sectional line A-A in FIG. 2B. The semiconductor laser apparatus 22 has a configuration substantially similar to that of the first embodiment of the invention, and a circuit board 4 is further connected to the block 2. A small-footprint is realized by mounting the circuit board 4 which forms an electrode structure, on the block 2. As the circuit board 4, a hard circuit board or a FPC may be used. In particular, the FPC can be easily machined and can incorporate an electronic circuit in a narrow space, thereby enabling downsizing of electronic apparatuses, and improving a degree of freedom with respect to a board shape. The circuit board 4 and the laser chip 3 are connected to each other by a wire 5, and a laser beam is emitted by applying a current.

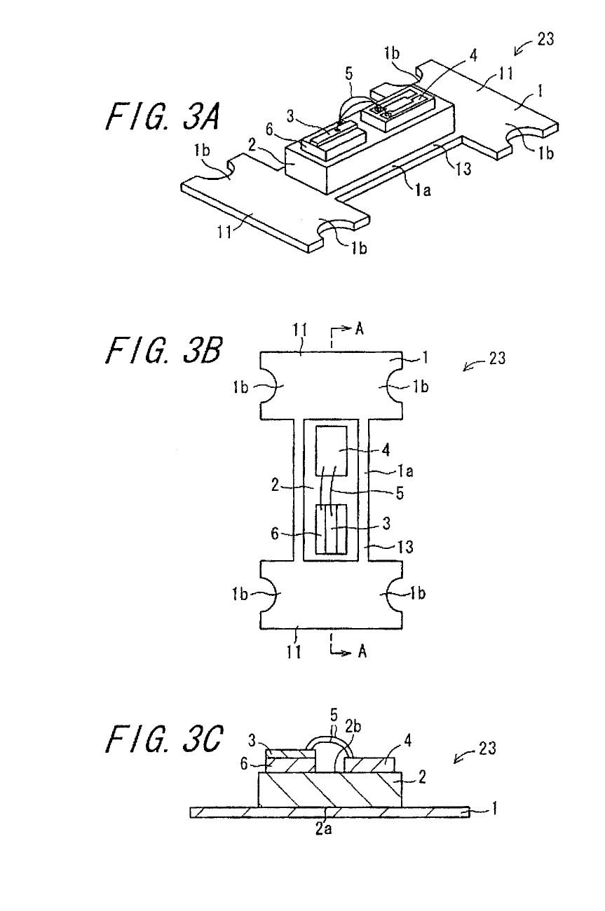

FIG. 3A is a perspective view illustrating a semiconductor laser apparatus 23 according to a third embodiment of the invention, FIG. 3B is a plan view thereof, and FIG. 3C is a cross-section view taken on cross-sectional line A-A in FIG. 3B. The semiconductor laser apparatus 23 has a configuration substantially similar to that of the second embodiment of the invention, and the laser chip 3 and the block 2 are connected to each other via a sub-mount 6. As the sub-mount 6, there may be used a material which has significantly high heat conductivity, is excellent in heat discharge capability, and has a buffering function for reducing a breakdown caused by stress produced by a difference in a heat expansion coefficient between the block 2 and the semiconductor laser chip. Therefore, deterioration of the semiconductor laser apparatus is prevented, and thereby its reliability is improved and its lifetime is increased.

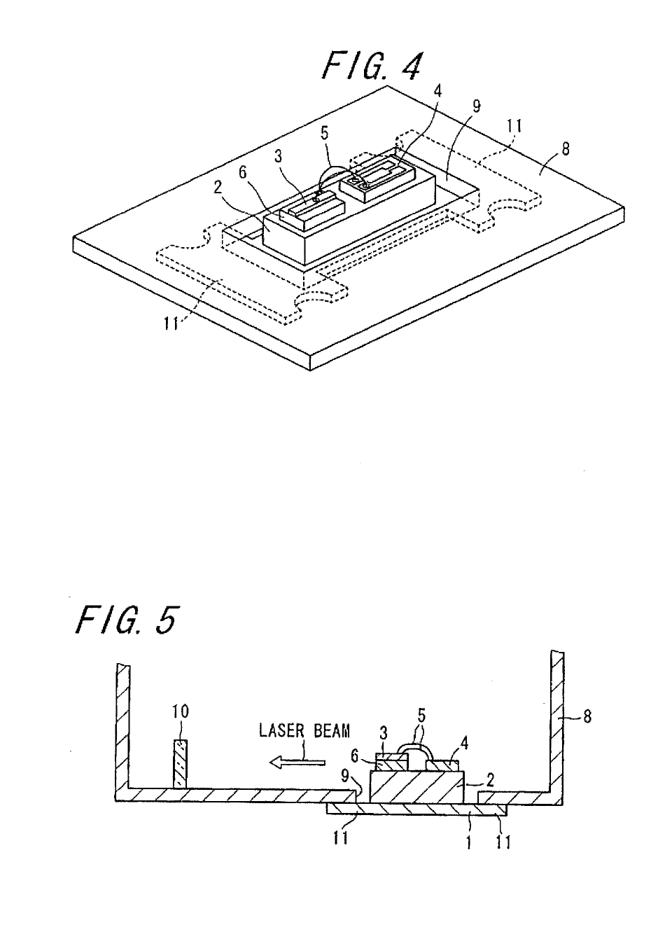

FIG. 4 is a perspective view illustrating a method for setting the semiconductor laser apparatus 23 of the invention. A through-hole 9 is provided in the housing 8 at a position in which the semiconductor laser apparatus is inserted, and the semiconductor laser apparatus 23 is fixed to the housing 8. At least the laser chip 3 of the semiconductor laser apparatus 23 is inserted into the through-hole 9 so as to be positioned inside the housing 8 of the optical pickup apparatus, and the plate 1 is temporarily fixed to the housing 8 by using a screw or a plate spring such that an outside surface of the housing 8 and the exposed portion 11 of the plate 1 partially overlap with each other, and then fixed to the hosing 8 by a solder or a resin paste containing a metal. By exposing a part of the semiconductor laser apparatus 23 outwardly from the housing 8, heat generated from the laser chip 3 can be discharged from the plate 1. Therefore, a heat discharge area can be increased, compared with a case in which the heat is discharged only through an electrode lead in a conventional manner, and thereby an efficiency of heat discharge is improved. Further, the plate 1 is connected to the housing 8 by a material containing a metal such as a solder, and thereby heat discharge from the plate 1 to the housing 8 is ensured. Therefore, the heat generated from the laser chip 3 can be sufficiently discharged, and deterioration of the semiconductor laser apparatus 23 can be prevented, and thereby its reliability can be improved, and its lifetime can be increased. Further, the laser chip 3 is fixed to a housing surface parallel to an optical axis of an output light beam, and thereby it is possible to adjust a position on the surface parallel to the optical axis of the output light beam by adjusting a position of the through-hole 9 which is provided in the housing 8. By adjusting a position as described above, it is possible to adjust an optical path length from a light-emitting position of a laser beam to a light-irradiated position thereof, without changing a size of the housing. In particular, it is possible to efficiently change the optical path length by changing a position of the through-hole 9 in an output direction of the light beam.

FIG. 5 is a view illustrating a method for setting the semiconductor laser apparatus 23. The semiconductor laser apparatus 23 is inserted into the through-hole 9 from an outside of the housing 8, and fixed to the housing 8. A laser beam emitted from the laser chip 3 mounted on the semiconductor laser apparatus 23 is emitted toward a lens 10. An optical path length from a light-emitting position of a laser beam, that is, a light-output position of the laser chip 3, to a light-irradiated position, that is, the lens 10, can be easily adjusted by changing a position at which the through-hole 9 is provided in an output direction of the laser beam, without changing a size of the housing 8.

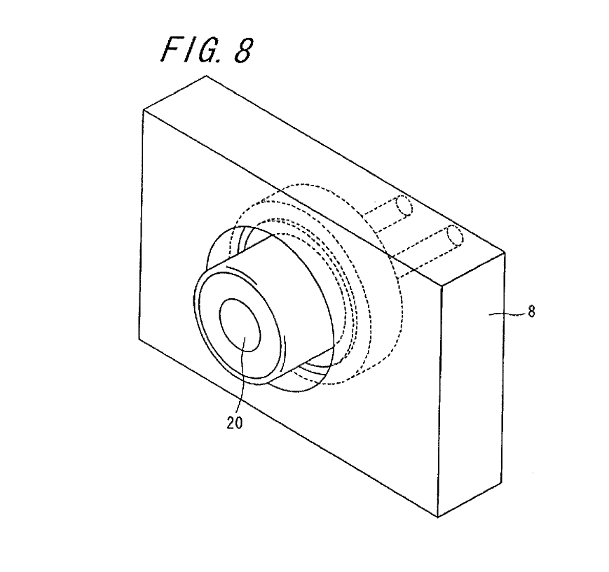

In a semiconductor laser apparatus 20 shown in FIG. 8, the semiconductor laser apparatus 20 is fixed to a housing surface perpendicular to an output direction of a light beam. Therefore, an optical path length cannot be adjusted, and a tilt adjustment cannot be carried out without using a laser holder as an additional component. However, in the semiconductor laser apparatus 23 of the invention, an optical path length can be adjusted, and by changing a fixing direction of the semiconductor laser apparatus 23 to a direction perpendicular to an output direction of a light beam, and in parallel to the housing surface to which the semiconductor laser apparatus 23 is fixed, the output direction of the light beam can be easily changed, and an adjustment range of the optical path length and the output direction can be increased.

Further, as shown in FIGS. 4 and 5, by increasing a length of the through-hole 9 in an output direction of a light beam longer than that of the block 2 in the output direction of the light beam, it becomes possible to finely adjust a connecting position of the plate 1 in the output direction of the light beam when the plate 1 is connected to the housing 8. Accordingly, a fine adjustment of the optical path length becomes possible without changing a position at which the through-hole 9 is provided. It is also possible to increase the adjustment range of the optical path length by providing the through-hole 9 having an even longer length in the output direction of the light beam. An irradiated object is not limited to a lens.

The through-hole 9 is provided to have a long length in the output direction of the light beam, allowing easy movement of the semiconductor laser apparatus 23 in the output direction of the light beam. Accordingly, the adjustment range is further increased to allow easy adjustment. However, in order to allow such movement of the semiconductor laser apparatus 23, it is necessary to provide an exposed portion 11 of the plate 1 in a width direction of the plate 1. In addition, by previously providing the plurality of through-holes 9, selecting the appropriate through-hole 9, and fixing the semiconductor laser apparatus 23 thereto, it becomes easy to adjust the optical path length.

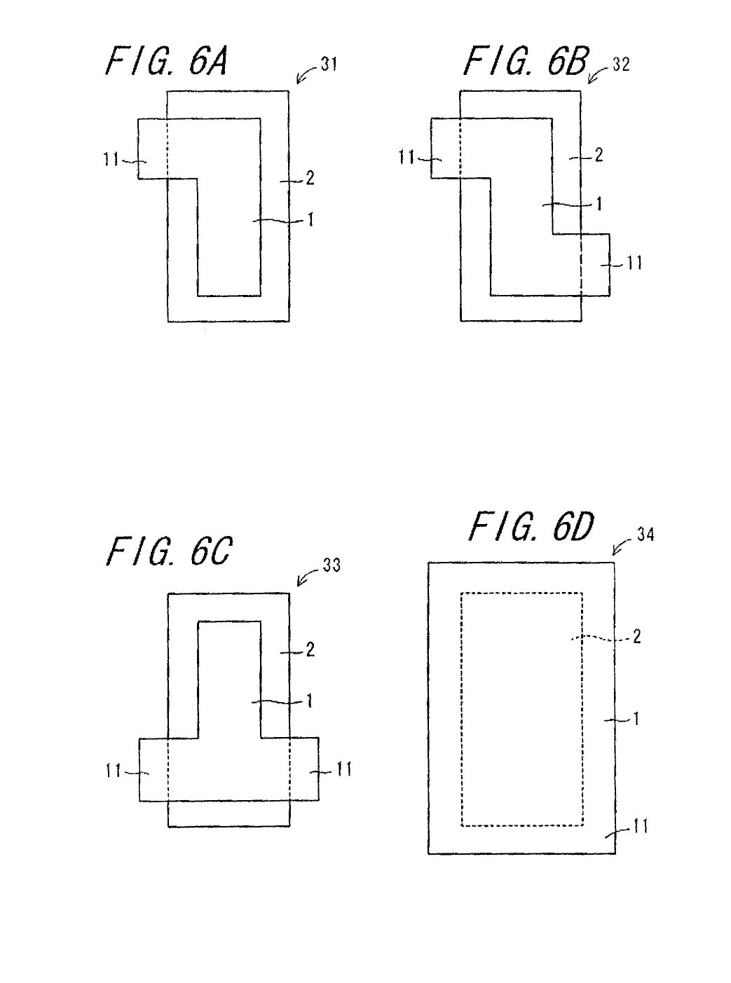

FIGS. 6A to 6D are bottom views schematically illustrating a shape of the exposed portion 11 which is formed by partially exposing a surface with which the plate 1 and the block 2 are connected. The semiconductor laser apparatus 31 shown in FIG. 6A is provided with the exposed portion 11 in at least one position. The plate 1 is partially exposed from a connecting surface between the block 2 and the plate 1, and thereby when disposed in the housing, the circuit board, and the block are inserted from an outside of the housing, and the exposed portion 11 of the plate 1 is connected to an outside surface of the housing, and fixed thereto. The plate 1 is exposed outwardly from the housing, and thereby heat generated from the laser chip in the housing is efficiently discharged through the sub-mount and the block to the plate 1, and to an outside of the housing. Accordingly, deterioration of the semiconductor laser apparatus can be prevented, and thereby its reliability can be improved, and its lifetime can be increased.

A shape of the exposed portion 11 of the semiconductor laser apparatus 32 shown in FIG. 6B is symmetric with respect to a center point of the surface of the block 2 to which the plate 1 is connected. Therefore, when the semiconductor laser apparatus is inserted from an outside of the housing and fixed to the housing, the connecting portion with the outside surface of the housing becomes symmetric, thereby further improving stability of the connection.

A shape of the exposed portion 11 of the semiconductor laser apparatus 33 is symmetric with respect to a straight line passing though a center point of the surface of the block 2 to which the plate 1 is connected, and perpendicular to a thickness direction of the plate 1. Therefore, when the semiconductor laser apparatus is inserted from an outside of the housing and fixed to the housing, the connecting portion with the outside surface of the housing becomes symmetric, thereby further improving stability of the connection.

In the semiconductor laser apparatus 34 shown in FIG. 6D, the surface of the block 2 to which the plate 1 is connected is entirely connected to the plate 1, and an area of a surface of the plate 1 to which the block 2 is connected larger than an area of a surface of the block 2 to which the plate 1 is connected. Therefore, the exposed portion 11 is entirely provided around the block 2. One surface of the block 2 is entirely connected to the plate 1, and the plate 1 has a wide area. Therefore, an efficiency of heat discharge is improved, and stability of the connection with the housing is improved. These shapes of the exposed portion 11 are not limited to the shapes shown in FIGS. 6A to 6D.

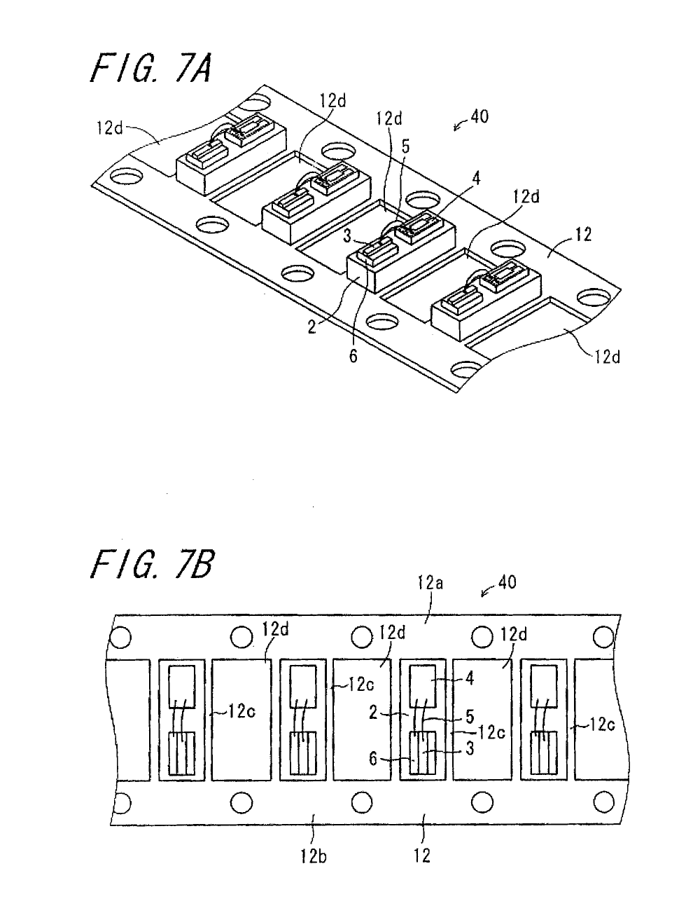

FIG. 7A is a perspective view illustrating a group of the semiconductor laser apparatuses of the invention, FIG. 7B is a plan view thereof. The semiconductor laser group 40 includes an elongated plate 12; the plurality of blocks 2 which are connected to one surface of the elongated plate 12 which is perpendicular to a thickness direction of the elongated plate 12, in a line at certain intervals in a longitudinal direction of the elongated plate 12; and the laser chip 3 which is connected to a surface opposite to a surface of the block 2 to which the elongated plate 12 is connected.

The elongated plate 12 has a ladder shape, and has a first extended portion 12a and a second extended portion 12b which extend in a longitudinal direction thereof so as to be parallel to each other and provided at an interval in a width direction thereof, and a plurality of third extended portions 12c which are provided at a certain interval in the longitudinal direction between the first extended portion 12a and the second extended portion 12b. The plurality of third extended portions 12c are coupled on the first extended portion 12a and the second extended portion 12b on both sides thereof, respectively. The respective third extended portions 12c become the connection portion 1a of the plate 1. That is, the elongated plate 12 is provided with a plurality of holes 12d at certain intervals in the longitudinal direction, in a middle portion in the width direction, and the blocks 2 having rectangular parallelepiped shapes are connected to portions in which the holes are not provided, that is, the third extended portions 12c. The elongated plate 12 is a base holder having a ladder shape. By means of a production system of the semiconductor laser apparatus, the base holder on which the base is mounted can be linearly moved along a linear rail, and a movement of the base from the base holder to a production processing apparatus, and a movement of the base from the production processing apparatus to the base holder can be carried out by using an arm. Therefore, this production system has a simple structure, sure operation, and a high production efficiency. Further, an optical axis of an output light beam from the laser chip 3 is perpendicular to a thickness direction of the elongated plate 12. The plurality of blocks 2 are connected to a sheet of the elongated plate 12 having a ladder shape, thereby facilitating a series of steps such as a set-up of components or an inspection.

There will be described a method for dividing the group of the semiconductor laser apparatuses between the blocks 2, and manufacturing the semiconductor laser apparatus. First, the group of the semiconductor laser apparatuses 40, as described above, is provided, and finally, the elongated plate 12 of the group of the semiconductor laser apparatuses 40 is divided between the adjacent blocks 2 to obtain the semiconductor laser apparatus. A dividing position of the elongated plate 12 may be selected anywhere as long as it is located between the adjacent blocks 2. The elongated plate 12 is preferably divided at a center position between the adjacent blocks 2. The exposed portions 11 of the plate 1 of the semiconductor laser apparatuses which are obtained after the separation have all the same shapes, allowing a stable supply of products having the same quality. In addition, a shape of the exposed portion 11 becomes symmetric, thereby increasing stability when the semiconductor laser apparatus is disposed in the housing.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

What is claimed is:

1. A semiconductor laser apparatus comprising:
a plate for connecting with a housing;
a block connected to one surface of the plate which is perpendicular to a thickness direction thereof; and
a laser chip which is connected to a surface opposite to a surface of the block to which the plate is connected,
wherein the plate is provided with an exposed portion which is partially exposed in the surface of the plate to which the block is connected, and an optical axis of an output light beam of the laser chip is perpendicular to the thickness direction of the plate.

2. The semiconductor laser apparatus of claim 1, further comprising a circuit board which is connected to a surface of the block which surface is opposite to the surface of the block to which the plate is connected,
wherein the laser chip and the circuit board are electrically connected to each other.

3. The semiconductor laser apparatus of claim 1, wherein the circuit board is a flexible board.

4. The semiconductor laser apparatus of claim 1, wherein the exposed portion is symmetric with respect to a center point of the surface of the block to which the plate is connected.

5. The semiconductor laser apparatus of claim 1 wherein the exposed portion is symmetric with respect to a straight line passing though a center point of the surface of the block to which the plate is connected, and perpendicular to a thickness direction of the plate.

6. The semiconductor laser apparatus of claim 1, wherein the surface of the block to which the plate is connected is entirely connected to the plate, and an area of the surface of the plate to which the block is connected is larger than that of the surface of the block to which the plate is connected.

7. The semiconductor laser apparatus of claim 1, wherein Further, in the invention, it is preferable that the laser chip is connected through a sub-mount member to the block, and the sub-mount has good heat conductivity, good heat discharge capability, and a buffering function.

8. A group of the semiconductor laser apparatuses comprising:
an elongated plate;
a plurality of blocks which are connected to one surface of the elongated plate which is perpendicular to a thickness direction of the elongated plate in a line at certain intervals in a longitudinal direction of the elongated plate; and
a laser chip which is connected to a surface opposite to a surface of the block to which the elongated plate is connected,
wherein an optical axis of an output light beam of the laser chip is perpendicular to the thickness direction of the elongated plate.

9. A method for manufacturing the semiconductor laser apparatus comprising the steps of:
providing the group of the semiconductor laser apparatuses of claim 8; and
dividing the elongated plate of the group of the semiconductor laser apparatuses between the adjacent blocks.

10. An optical pickup apparatus comprising:
the semiconductor laser apparatus of claim 1; and
a housing having a through-hole,
wherein an area of opening of the through-hole is larger than that of a surface perpendicular to a thickness direction of the block, and at least the laser chip of the semiconductor laser apparatus is inserted into the through-hole so as to be positioned in the housing, and the exposed portion is fixed to an outside surface of the housing so as to partially overlap with each other.
